(19) United States
(12) Patent Application Publication
(10) Pub. No.: US 2021/0005442 A1
(43) Pub. Date: Jan. 7, 2021

(54) APPARATUS AND METHOD FOR ENHANCING SIGNAL INTENSITY OF RADIO FREQUENCY GLOW DISCHARGE MASS SPECTROMETRY

(71) Applicant: SHANGHAI INSTITUTE OF CERAMICS, CHINESE ACADEMY OF SCIENCES, Shanghai (CN)

(72) Inventors: Rong QIAN, Shanghai (CN); Shangjun ZHUO, Shanghai (CN); Lei ZHOU, Shanghai (CN); Yueqin ZHU, Shanghai (CN)

(21) Appl. No.: 16/980,574

(22) PCT Filed: Apr. 2, 2019
(86) PCT No.: PCT/CN2019/081067

§ 371 Date: Sep. 14, 2020

(30) Foreign Application Priority Data
Apr. 4, 2018 (CN) 201810301629.8
Apr. 4, 2018 (CN) 201810301634.9
Apr. 4, 2018 (CN) 201810301640.4

(51) Int. Cl. H01J 49/10; G01N 27/68; H01J 49/04

(52) U.S. Cl. CPC H01J 49/105; H01J 49/04; G01N 27/68

(57) ABSTRACT

Regarding the problem of low signal intensity during material analysis using existing radio frequency glow discharge mass spectrometry, an apparatus and method for enhancing signal intensity of radio frequency glow discharge mass spectrometry are provided, so as to enhance the signal intensity during inorganic material analysis using a radio frequency glow discharge mass spectrometer. The apparatus comprises a sample introduction cell having a sample introduction rod and having a sample fixed thereon, and an array magnet enhancement portion having a housing shell and magnets arranged in an array. The array magnet enhancement portion is fixed between the sample introduction rod in the sample introduction cell and the sample and is tightly attached to the sample.

### TECHNICAL FIELD

The present invention belongs to the technical field of inorganic mass spectrometry analysis. Specifically, the present invention relates to the technical field of material analysis using a radio frequency glow discharge mass spectrometer, and more specifically, the present invention relates to an apparatus and method for enhancing signal intensity of radio frequency glow discharge mass spectrometry by using magnets.

### TECHNICAL BACKGROUND

The glow discharge mass spectrometry (GD-MS) method has advantages of directly solid injection, high sensitivity, small matrix effect, analysis of more than 70 elements at once, etc., and is widely used in trace element analysis of high-purity conductor materials. In recent years, radio frequency glow discharge mass spectrometry has received much attention due to its ability to directly analyze conductor, semiconductor, and non-conductor materials. In the radio frequency mode, the charged particles move back and forth between the electrodes under the action of electric field force. Taking a cycle as an example, in the negative half cycle of the radio frequency source, a large number of positive ions move to the surface of the sample, the sample accumulates a large amount of positive charge, and in the positive half cycle of the radio frequency source, a large number of electrons move to the surface of the sample and neutralize the positive charge, thereby achieving continuous discharge of non-conductor materials. Since the movement ability of the electrons is much higher than that of the positively charged ions, the negative bias formed on the surface of the sample allows the positively charged ions to continuously bombard the sample. However, when using radio frequency glow discharge mass spectrometry to analyze semiconductor and non-conductor materials, due to the poor thermal conductivity of the material, the power of the radio frequency source is severely restricted, resulting in a low test signal, which affects the analysis sensitivity.

### SUMMARY OF THE INVENTION

### Technical Problem

In glow discharge, cathode sputtering occurs in the cathode dark space and Penning ionization occurs in the negative glow space, and these are two key factors that affect the signal intensity. Improving the efficiency of sputtering and ionization is an important idea to improve the test effect. In this regard, in some radio frequency glow discharge instruments, such as rf-GD-OES, rf-GD-AES, etc., use of external magnets to enhance signal intensity has been reported in relevant literature. After the external magnet is applied, the electrons are bound and move on the surface of the sample by the magnetic field under the action of the Lorentz force, which improves the sputtering efficiency, and the signal intensity of the elements in the sample is improved to a great extent. Under the action of the external magnetic field, the signal intensity of the matrix element and impurity element in the sample are improved to a certain extent. However, since the material, size of the magnet, and the distribution of magnetic induction intensity are fixed, the magnetic field cannot be adjusted in real time during the test, and therefore the control of the signal intensity needs to be improved.

### SOLUTION TO THE PROBLEM

### Technical Solution

The present invention aims at the problem of low signal intensity during material analysis using existing radio frequency glow discharge mass spectrometry, and provides an apparatus and method for enhancing signal intensity of radio frequency glow discharge mass spectrometry using magnets, so as to enhance the signal intensity during inorganic material analysis using a radio frequency glow discharge mass spectrometer.

The first kind of apparatus and method of the present invention: on one hand, an apparatus for enhancing signal intensity of radio frequency glow discharge mass spectrometry using array magnets is provided,

which comprises:

a sample introduction cell having a sample introduction rod and having ceramic gaskets fixed thereon; and

an array magnets enhancement portion having a housing shell and magnets arranged in array.

The array magnets enhancement portion is fixed between the sample introduction rod and the sample in the sample introduction cell, and is tightly attached to the sample.

The array magnet enhancement portion improves the performance of radio frequency glow discharge mass spectrometer for material analysis. The structure of the present invention is simple and reasonable, which effectively improves the signal intensity and analysis sensitivity of the instrument, is suitable for glow discharge mass spectrometer or similar devices.

Preferably, the material of the housing shell is metal or alloy.

Preferably, the housing shell can be a cylinder, a cuboid, or a cube.

The outer diameter of the housing shell is less than or equal to the inner diameter of the sample introduction cell, and the height of the housing shell is less than the height of the sample introduction cell.

Preferably, the magnets arranged in an array composed of a plurality of permanent magnets with same direction of magnetic induction Lines.

Preferably, the magnets arranged in the array are tightly attached to the upper and lower surfaces of the housing shell.

Preferably, the magnets arranged in the array are placed in the housing shell, and direction of magnetic induction of each magnet is parallel to the sample.

The sample can include: sample of conductors, semiconductors, non-conductor materials.

On the other hand, a method for enhancing signal intensity of radio frequency glow discharge mass spectrometry using array magnets is provided, using an apparatus comprises a sample introduction cell having a sample introduction rod and having a sample fixed thereon, and an array magnets enhancement portion having a housing shell and magnets arranged in an array, comprises the following steps:

installing and fixing the array magnets enhancement portion between the sample introduction rod and the sample in the sample introduction cell, and making it tightly attach to the sample;

turning on the radio frequency source, so that the current passes through the sample introduction rod and the housing shell and is conducted to the sample, and the apparatus forms a magnetic field on the side of the sample which near the discharge chamber; and

scanning elements to be tested of the sample and recording the signal intensity.

In this method, the means is placed between the sample introduction rod and the sample, after the radio frequency power supply is activated, the current passes through the sample introduction rod and the metal housing shell and is conducted to the sample, and the array magnets enhancement portion forms a magnetic field on the side of the sample which near the discharge chamber and generate an oscillating magnetic field, thereby extending the movement path of electrons, increasing the collision probability of electrons and neutral particles, improving the ionization efficiency, and thus improving the ion signal intensity.

The second kind of apparatus and method of the present invention: on one hand, an apparatus for enhancing signal intensity of radio frequency glow discharge mass spectrometry using a ring magnet is provided,

which comprises:

a sample introduction cell having a sample introduction rod and having ceramic gaskets fixed thereon; and

a ring magnet enhancement portion having a housing shell and a ring magnet.

The ring magnet is placed in the housing shell, and the ring magnet enhancement portion is fixed between the sample introduction rod and the ceramic gaskets in the sample introduction cell.

The use of the ring magnet enhancement portion improves the performance of radio frequency glow discharge mass spectrometer for material analysis. The structure of the apparatus is simple, the sample of inorganic materials analyzed with the apparatus of the present invention include: conductors, semiconductors, non-conductor materials, etc. Using conductor materials is not needed, and sample preparation work is not complicated, so as to avoid pollution and reduce analysis costs. During discharge, the signal intensity is high, the discharge is stable, and the signal-to-noise ratio (S/N) is ideal, which shortens the analysis time and improves the analysis efficiency.

Preferably,

the material of the housing shell is metal or alloy.

The housing shell can be a hollow cylinder, a hollow cube, or a hollow cuboid.

It is also can be that, in the case of the housing shell is a hollow cylinder, the outer diameter of the ring magnet is less than the outer diameter of the housing shell, the inner diameter of the ring magnet is greater than the inner diameter of the housing shell, and the height of the ring magnet is less than the height of the housing shell.

Preferably, the sample to be tested is placed in an inner hole of the ring magnet.

In this way, the sample to be tested can be surrounded to form a magnetic field enhancement portion, the sample is embedded in the ring magnet, after the radio frequency power supply is activated, the current passes through the sample introduction rod and the housing shell and is conducted to the sample. The structure of the present invention is simple and reasonable, which effectively improves the signal intensity and analysis sensitivity of the instrument, is suitable for element analysis of inorganic materials, and is convenient to use.

The sample can include: sample of conductors, semiconductors, non-conductor materials.

On the other hand, a method for enhancing signal intensity of radio frequency glow discharge mass spectrometry using a ring magnet is provided, using an apparatus comprising a sample introduction cell having a sample introduction rod and having ceramic gaskets fixed thereon, and a ring magnet enhancement portion having a housing shell and a ring magnet, comprises the following steps:

installing and fixing the ring magnet enhancement portion between the sample introduction rod and the ceramic gaskets in the sample introduction cell;

embedding the sample into an inner hole of the ring magnet;

connecting the radio frequency source, and adjusting to proper discharge pressure and radio frequency source power to discharge; and

scanning elements to be tested of the sample and recording the signal intensity.

The ring-shaped magnetic field enhancement part has a ring-shaped magnetic induction lines distribution. Under the action of the electric field force and the Lorentz force, the electrons make a spiral movement around the magnetic induction lines, and the movement path of electrons is extended, which greatly increases the collision probability of electrons and the atoms. Compared with the case without a magnetic field, the ionization efficiency is improved. In addition, more argon ions generated by ionization bombard the surface of sample under the action of the electric field, so that the sputtering rate is also increased.

The third kind of apparatus and method of the present invention: on one hand, an apparatus for enhancing signal intensity of radio frequency glow discharge mass spectrometry using an adjustable magnetic field is provided,

which comprises:

a sample introduction cell having a sample introduction rod and having a sample fixed thereon; and

an adjustable magnetic field enhancement portion having a housing shell and an electromagnet composed of an energized solenoid and an iron core.

The electromagnet is placed in the housing shell.

The adjustable magnetic field enhancement portion is fixed between the sample introduction rod and the sample in the sample introduction cell.

When analyzing metal, semiconductor, and non-conductor materials with this apparatus, using conductor materials is not needed and sample preparation work is not complicated, so as to avoid pollution and reduce analysis costs. During discharge, the signal intensity is high, the discharge is stable, the magnetic induction intensity can be adjusted by changing the current of the energized solenoid, and then the signal intensity can be adjusted to obtain the ideal signal-to-noise ratio (S/N), shortening the analysis time and improving the analysis efficiency. The magnetic field generated by the energized solenoid is mainly used to improve the performance of the radio frequency glow discharge mass spectrometer for material analysis, and the magnetic field strength is adjusted by adjusting the strength of coil current, thereby realizing real-time control of the signal intensity.

Preferably, the material of the housing shell is metal or alloy.

Preferably, the housing shell is a cylinder, a cube, or a cuboid.

The outer diameter of the housing shell is less than or equal to the inner diameter of the sample introduction cell, and the height of the housing shell is less than the height of the sample introduction cell.

Preferably, the length of the electromagnet is less than the inner diameter of the housing shell, the diameter of the electromagnet is less than the height of the housing shell, and the number of coil turns is n≥5.

Preferably, the electromagnet is fixed in the housing shell using insulating material.

The lead of the energized solenoid passes through two small holes on the side of the housing shell and connects to the power supply.

The power supply can be DC power supply or AC power supply.

The sample can include: sample of conductors, semiconductors, and non-conductor materials.

On the other hand, a method for enhancing signal intensity of radio frequency glow discharge mass spectrometry using an adjustable magnetic field is provided, using an apparatus comprises a sample introduction cell having a sample introduction rod and having a sample fixed thereon, and an adjustable magnetic field enhancement portion having a housing shell and an electromagnet composed of an energized solenoid and an iron core, comprises the following steps:

putting the adjustable magnetic field enhancement portion between the sample and the sample introduction rod;

making the lead of the energized solenoid pass through small holes on the side of the housing shell and connect to the power supply;

connecting the radio frequency source, and adjusting to proper discharge pressure and radio frequency source power to discharge; and

scanning elements to be tested of the sample and record the signal intensity.

The adjustable magnetic field enhancement portion generates magnetism under the condition of solenoid energization, the greater the energization current, the stronger the magnetism. Under the action of the electric field force and the Lorentz force, the electrons make a spiral movement around the magnetic induction lines, and the movement path of electrons is extended, which greatly increases the collision probability of electrons and the atoms. Compared with the case without a magnetic field, the ionization efficiency is improved. In addition, more argon ions generated by ionization bombard the surface of sample under the action of the electric field, so that the sputtering rate is also increased, and then the signal is enhanced. The signal strength is related to the current of the energized solenoid.

### BENEFICIAL EFFECTS OF INVENTION

### Beneficial Effects

During non-conductor materials (crystals, ceramics, powders, etc.) analysis or in-depth analysis, radio frequency glow discharge mass spectrometry (rf-GD-MS) has key technical problems such as low ion signal intensity and low sensitivity, etc., which restricts the use of rf-GD-MS in the field of new materials. The invention of an apparatus and method for enhancing signal intensity of radio frequency glow discharge mass spectrometry can regulate the movement behavior of discharge gas particles and electrons (which plays a leading role in the ionization process) during the glow ionization process. Without the magnetic field action, the movement path of electrons is relatively simple and the ionization efficiency is low. Under the synergistic effect of electric field force and Lorentz force, the movement path of electrons will be effectively bent and extended, thereby increasing the collision probability of electrons and neutral particles in the plasma, improving ionization efficiency, and thus improving sensitivity of rf-GD-MS analysis. The apparatus and method of the present invention will effectively solve the key technical problem of low sensitivity of rf-GD-MS analysis, and promote the development and application of rf-GD-MS at the same time.

### BRIEF DESCRIPTION OF THE DRAWINGS

### Drawings Description

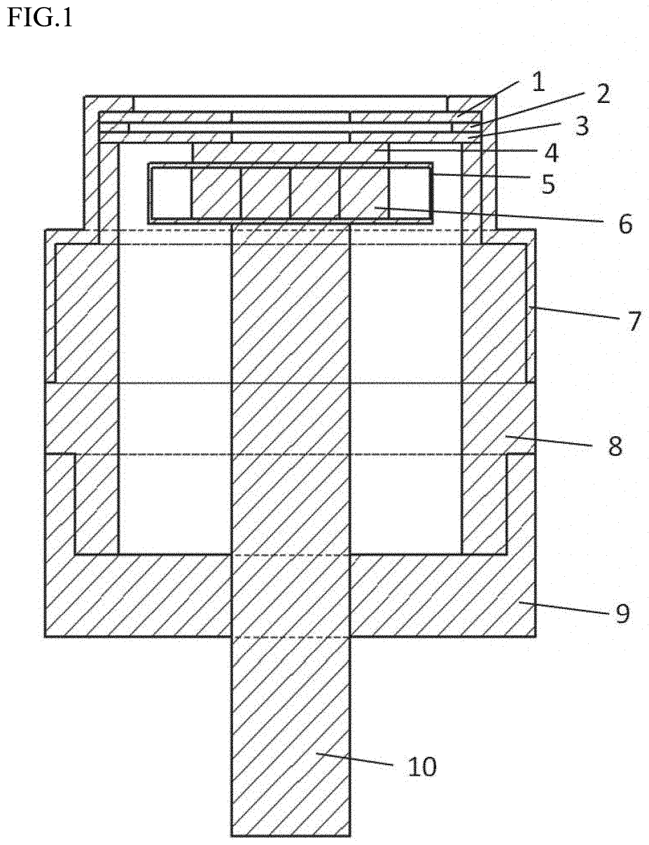

FIG. 1 shows the sectional view of the sample introduction cell in the apparatus for enhancing signal intensity of radio frequency glow discharge mass spectrometry by array magnets according to an embodiment of the present invention.

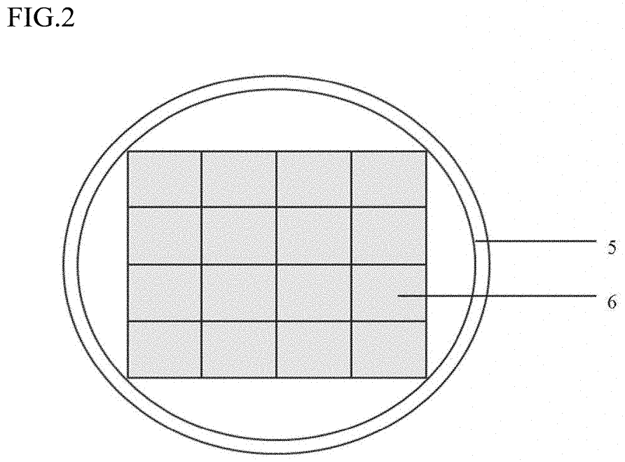

FIG. 2 shows the top view of the array magnets enhancement portion in the apparatus for enhancing signal intensity of radio frequency glow discharge mass spectrometry by array magnets according to an embodiment of the present invention.

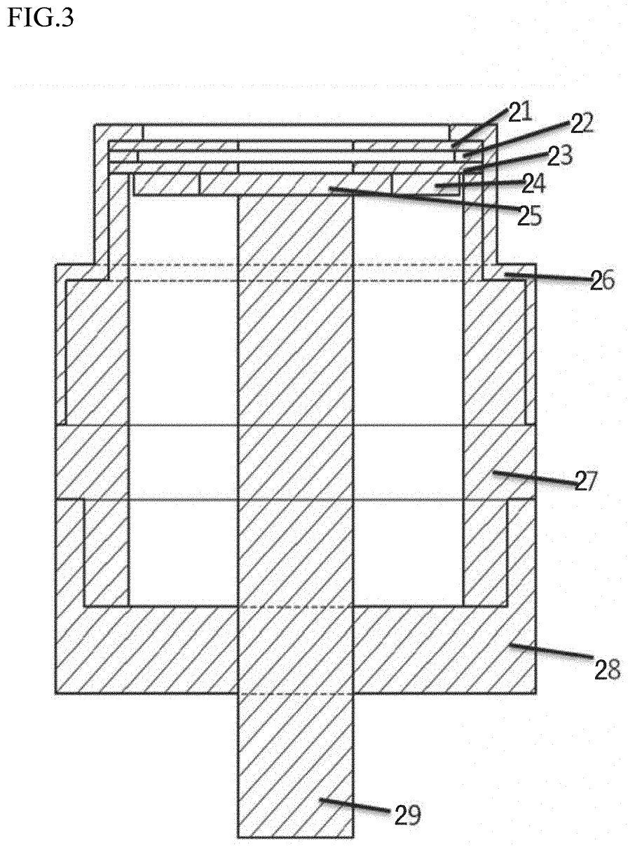

FIG. 3 shows the sectional view of the sample introduction cell in the apparatus for enhancing signal intensity of radio frequency glow discharge mass spectrometry by a ring magnet according to an embodiment of the present invention.

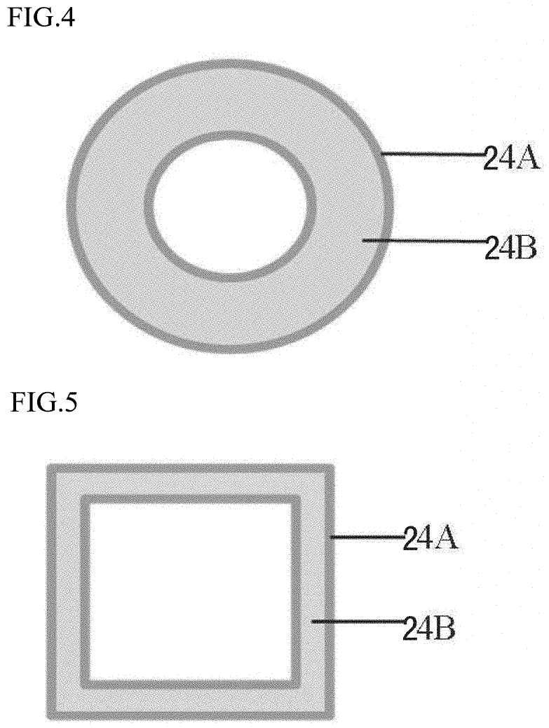

FIG. 4 shows the top view of the ring magnet enhancement portion in the apparatus for enhancing signal intensity of radio frequency glow discharge mass spectrometry by a ring magnet according to an embodiment of the present invention.

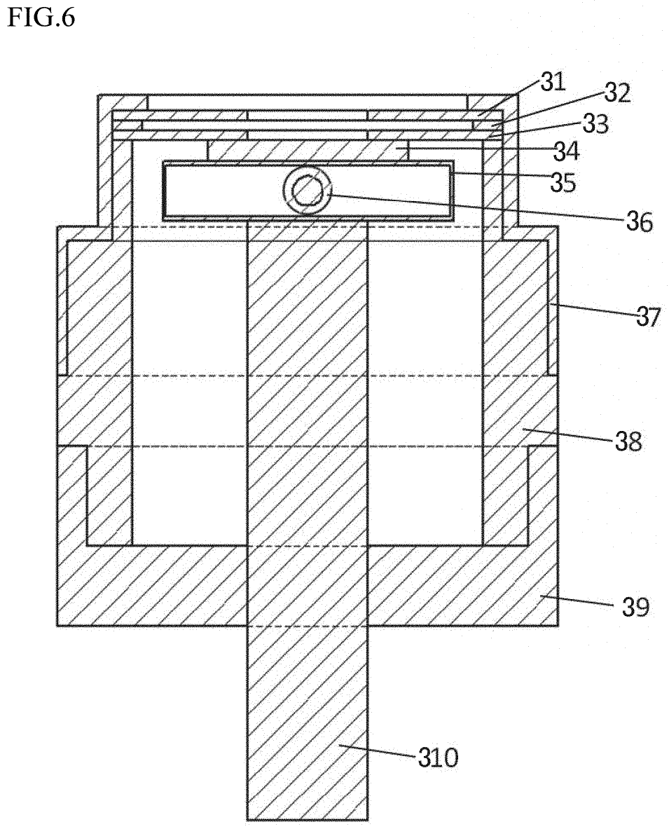

FIG. 5 shows the top view of the ring magnet enhancement portion in the apparatus for enhancing signal intensity of radio frequency glow discharge mass spectrometry by a ring magnet according to the second embodiment of the present invention.

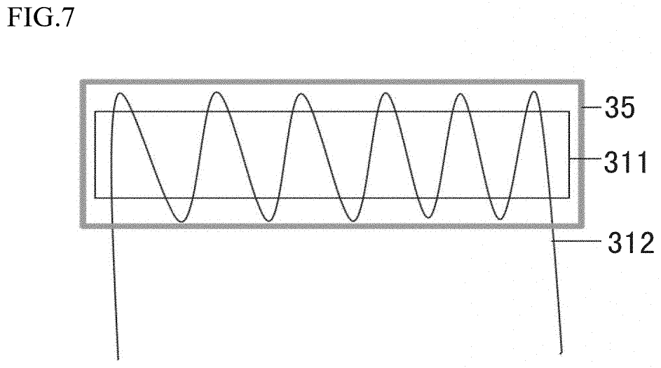

FIG. 6 shows the sectional view of the sample introduction cell in the apparatus for enhancing signal intensity of radio frequency glow discharge mass spectrometry by using adjustable magnetic field according to an embodiment of the present invention.

FIG. 7 shows the top view of the adjustable magnetic field enhancement portion in the apparatus for enhancing signal intensity of radio frequency glow discharge mass spectrometry by using adjustable magnetic field according to an embodiment of the present invention.

### BEST EMBODIMENTS FOR IMPLEMENTING THE INVENTION

### Best Embodiments of the Present Invention

The present invention is further described below with reference to the accompanying drawings and the following embodiments. It should be understood that the drawings and the following embodiments are only used to illustrate the present invention, but not to limit the present invention.

The present invention provides an apparatus for enhancing signal intensity of radio frequency glow discharge mass spectrometry by using magnets, which is applied to the radio frequency glow discharge mass spectrometer and belongs to the technical field of inorganic mass spectrometry analysis, and it is mainly used to analyze inorganic materials (including: conductor, semiconductor, and non-conductor materials) in the radio frequency power supply mode, so as to solve the problems such as low signal intensity, low sensitivity, etc., which exist in the existing mass spectrometry apparatuses.

The first kind of apparatus provided by the present invention is an apparatus for enhancing signal intensity of radio frequency glow discharge mass spectrometry by array magnets.

FIG. 1 shows the sectional view of the sample introduction cell in the apparatus for enhancing signal intensity of radio frequency glow discharge mass spectrometry by array magnets according to an embodiment of the present invention.

As shown in FIG. 1, the apparatus for enhancing signal intensity of radio frequency glow discharge mass spectrometry by array magnets according to the embodiment mainly comprises: a sample introduction cell having a sample introduction rod 10 and having a sample 4 fixed thereon, and an array magnets enhancement portion having a housing shell 5 and magnets arranged in an array (array magnets 6). The array magnets enhancement portion is fixed between the sample introduction rod 10 and the sample 4 in the sample introduction cell and is tightly attached to the sample 4.

More specifically, a tantalum sheet 1, ceramic gaskets 2, 3, and the sample 4 are placed flat above the housing shell 5 in turn. The surfaces of the tantalum sheet 1 and the ceramic gaskets 2, 3 are flat and smooth. The ceramic gaskets 2, 3 are insulated and used to maintain vacuum; the tantalum sheet 1 is used for electrical conduction, which is movably placed between the ceramic gaskets 2, 3 and the top of the sample introduction cell for easy disassembly and cleaning. The upper and lower surfaces of the sample 4 and the housing shell 5 are smooth surfaces. The array magnets 6 are placed inside the housing shell 5, and the upper and lower surfaces of the array magnets 6 are tightly attached the housing shell 5. Sheet sample cells 7, 8, 9 are connected together, and the sample cells are viewed as a whole from the outside. The sample introduction rod 10 is connected to the housing shell 5 for fixing the tantalum sheet 1, the ceramic gaskets 2, 3, the sample 4, and the housing shell 5. There is a spring which is not shown in drawings between the sample introduction rod 10 and the housing shell 5 to clamp them. FIG. 2 shows the top view of the array magnets enhancement portion in the apparatus for enhancing signal intensity of radio frequency glow discharge mass spectrometry by array magnets according to an embodiment of the present invention. FIG. 2 shows the array magnets enhancement portion by taking a cylindrical housing shell and 4×4=16 array magnets as an example. The housing shell 5 and the array magnets 6 placed inside constitute the array magnets enhancement portion.

The material of the housing shell 5 can be metal (such as copper) or alloy (such as brass), and the shape of the housing shell 5 can be cylindrical, cuboid, cubic, etc., and the upper and lower surfaces of the housing shell 5 are smooth and flat. The array magnets 6 are magnets arranged in array. The array magnets 6 are preferably composed of a plurality of permanent magnets with same direction of magnetic induction Lines.

The outer diameter (diameter) of the housing shell 5 is less than or equal to the inner diameter of the sample introduction cell in FIG. 1, and the height of the housing shell 5 is less than the height of the sample introduction cell.

The directions of magnetic induction of the array magnets 6 are parallel to the sample 4, and the upper and lower surfaces of the array magnets 6 are tightly attached the housing shell 5.

With the above-mentioned apparatus, the samples that can be analyzed with radio frequency glow discharge mass spectrometry can be samples of inorganic materials, including: conductors, semiconductors, non-conductor materials, etc.

As shown in FIG. 2, when the above-mentioned apparatus is used to analyze inorganic materials by radio frequency glow discharge mass spectrometry, the array magnets enhancement portion is placed between the sample introduction rod 10 and the sample 4 in the sample introduction cell and fixed by being clamped. After the radio frequency power supply is activated, the current passes through the sample introduction rod 10 and the housing shell 5 and is conducted to the sample 4, and the array magnets enhancement portion forms a magnetic field on the side of the sample 4 which near the discharge chamber. Compared with not use magnetic field or the use of a whole magnetic field, the array magnets enhancement portion can generate an oscillating magnetic field, thereby extending the movement path of electrons, increasing the collision probability of electrons and neutral particles, improving the ionization efficiency, and thus, improving the ion signal intensity.

The array magnets 6 in the present invention can be permanent magnet blocks with the same or different sizes and the same direction of magnetic induction lines. They are combined into an array distribution according to the magnetism of themselves. The size of the array is m×n (m is row, n is column, m≥2, n≥2, m and n can be equal or not equal). For the array magnets 6, the magnet model number can be selected from different magnet model numbers according to the need of magnetic field strength (for example, magnet whose model number N35, coercive force 876 kA/m, and permeability 1.05 can be selected), the total height of the magnets is less than the height of the housing shell.

### EMBODIMENTS OF THE INVENTION

### Embodiments of the Present Invention

The first kind of apparatus and its beneficial effects of the present invention will be specifically described below through embodiment 1 and embodiment 2.

### Embodiment 1

The metal material is processed into a cylindrical housing shell (taking brass material and cylindrical shape as an example) at normal temperature and pressure. The dimensions of the brass housing shell are: diameter 3 mm, height 5 mm, brass housing shell thickness 0.5 mm. 16 magnets (taking N35 NdFeB magnet as an example) with unit size of 5 mm×5 mm×5 mm are arranged to constitute a dot matrix magnet structure (taking 4×4 as an example) according to their magnetism. Put the magnet structure into the brass housing shell to constitute an array-shaped magnetic field signal enhancement means (array magnets enhancement portion).

When in use, place the array magnets enhancement portion between the sample introduction rod 10 and the sample 4 in the sample introduction cell, after the radio frequency power supply (not shown in drawings) is activated, the current passes through the sample introduction rod 10 and the housing shell 5 and is conducted to the sample 4, and the means forms a magnetic field on the side of the sample 4 which near the discharge chamber.

After use, if the array magnets enhancement portion is taken out and kept away from strong current and heat, while avoiding knocking and violent vibration, it can be reused.

### Embodiment 2

The present invention is further described below through another embodiment. In the following embodiment, the signal intensity of typical elements detected by a radio frequency glow discharge mass spectrometer with the array magnets enhancement portion is compared with the signal intensity of typical elements detected by a radio frequency glow discharge mass spectrometer without the array magnets enhancement portion; the greater the difference between them, the better the signal enhancement effect. The relative standard deviation (RSD %) is used to indicate the discharge stability of the non-conductor samples analyzed with the new apparatus; the lower the value, the better the stability.

Taking the analysis of the non-conductor material by using the array magnets enhancement portion as an example, the original yttrium oxide (Y₂O₃), B₁₂SiO₂₀ (BSO) and Ba_{5.52}La_{0.32}Ti₂Nb₈O₃₀ (BTN) material are processed into a disc-shaped sample. The dimensions of the sample are: cross-sectional diameter 20 mm, thickness 2 mm; washing the sample with nitric acid (HNO₃), ultrapure water and ethanol, then drying. Subsequently, the samples are rf-GD-MS analyzed under the conditions of radio frequency source power: 30 W and discharge gas (Ar) flow rate: 1.1 cc/min. Y in Y₂O₃, Bi in BSO and Ba in BTN are detected by rf-GD-MS with the array magnets enhancement portion, the signal intensity of the ions are: 2.28×10⁻¹¹ A, 3.05×10⁻¹¹ A, 2.59×10⁻¹¹ A, the relative standard deviations RSD (%) are: 8.9, 9.1, 9.3. Y in Y₂O₃, Bi in BSO and Ba in BTN are detected by rf-GD-MS without the array magnets enhancement portion, the signal intensity of the ions are: 9.54×10⁻¹² A, 1.65×10⁻¹¹ A, 1.03×10⁻¹¹ A, the relative standard deviations RSD (%) are: 10.5, 11.5, 12.7. The comparison result shows that the signal intensity of the ions and discharge stability obtained by rf-GD-MS analysis when using the array magnets enhancement portion have been significantly enhanced and improved.

The second kind of apparatus provided by the present invention is an apparatus for enhancing signal intensity of radio frequency glow discharge mass spectrometry by a ring magnet.

FIG. 3 shows the sectional view of the sample introduction cell in the apparatus for enhancing signal intensity of radio frequency glow discharge mass spectrometry by a ring magnet according to an embodiment of the present invention.

As shown in FIG. 3, the apparatus for enhancing the signal intensity of the radio frequency glow discharge mass spectrometry with a ring magnet according to the embodiment mainly comprises: a sample introduction device having a sample introduction rod 29 and having a ceramic gasket 23 fixed thereon;

and a ring magnet enhancement portion 24 having a housing shell 24A and a ring magnet 24B.

The ring magnet 24B is placed in the housing shell 24A, and the ring magnet enhancement portion is fixed between the sample introduction rod 29 and the ceramic gasket 23 in the sample introduction cell.

More specifically, a tantalum sheet 21 and ceramic gaskets 22, 23 are placed flat above the ring magnet enhancement portion 24 in turn. The surfaces of the tantalum sheet 21 and the ceramic gaskets 22, 23 are flat and smooth. The ceramic gaskets 22, 23 are insulated and used to maintain vacuum; the tantalum sheet 21 is used for electrical conduction, which is movably placed between the ceramic gaskets 22, 23 and the top of the sample introduction cell for easy disassembly and cleaning. A sample 25 is embedded inside the ring magnet enhancement portion 24. Sheet sample cells 26, 27, 28, are connected together, and the sample cells are viewed as a whole from the outside. The sample introduction rod 29 is connected to the ring magnet enhancement portion 24 for fixing the tantalum sheet 21, the ceramic gaskets 22, 23, the ring magnet enhancement portion 24 and the sample 25. FIG. 5 shows the top view of the ring magnet enhancement portion in the shape of a hollow cylinder. The material of the housing shell 24A can be metal (such as copper) or alloy (such as brass). The outer diameter (diameter) of the housing shell is less than or equal to the inner diameter of the sample introduction cell, the diameter of the inner hole of the housing shell is greater than the diameter of the sample and less than the outer diameter (diameter) of the housing shell, and the height of the housing shell is less than the height of the sample introduction cell.

The magnet model number can be selected from different magnet model numbers according to the need of magnetic field strength (for example, magnet whose model number N35, coercive force 876 kA/m, and permeability 1.05 can be selected). The outer diameter of the magnet is less than the outer diameter of the housing shell, and the inner diameter of the magnet is greater than the diameter of the inner hole of the housing shell, the height of the magnet is less than the height of the housing shell. In the case of a hollow cylinder, the magnetization direction is radial. In the case of a hollow cube or a hollow cuboid, the magnetization direction is parallel to the surface of the sample.

In the present invention, the housing shell 24A can be not only a hollow cylinder, but also a hollow cube or a hollow cuboid. For example, FIG. 5 shows a top view of the ring magnet enhancement portion in the shape of a hollow cube.

When using the glow discharge mass spectrometer with the ring magnet enhancement portion to analyze the material, the sample 25 is embedded in the inner hole of the ring magnet 24B, after the ring-shaped magnetic field enhancement portion and the sample are combined together, they are put into the sheet-shaped sample introduction cell. Then the radio frequency source is connected, proper discharge pressure and radio frequency source power are adjusted to discharge.

With the above-mentioned apparatus, the samples that can be analyzed with radio frequency glow discharge mass spectrometry can be samples of inorganic materials, including: conductors, semiconductors, non-conductor materials, etc.

The manufacturing of the apparatus for enhancing signal intensity of analysis of non-conductor material by glow discharge mass spectrometer includes the following steps:

process the ring magnet 24B;

process the housing shell 24A in the shape of a hollow cylinder, hollow cube or hollow cuboid, the material of the housing shell 24A is metal or alloy; and

put the ring magnet 24B into the housing shell 24A to constitute a ring magnet enhancement portion.

The method for enhancing the signal intensity of radio frequency glow discharge mass spectrometry using the above apparatus includes the following steps:

install and fix the ring magnet enhancement portion between the sample introduction rod 29 and the ceramic gaskets in the sample introduction cell;

embed the sample into the inner hole of the ring magnet 24B;

connect the radio frequency source, and adjust to proper discharge pressure and radio frequency source power to discharge; and

scan elements to be tested of the sample and record the signal intensity.

The second kind of apparatus and its beneficial effects of the present invention will be specifically described below through embodiment 3 and embodiment 4.

### Embodiment 3

The metal material is processed into the hollow cylindrical housing shell 21 (taking brass material and hollow cylindrical shape as an example) at normal temperature and pressure. The dimensions of the brass housing shell are: outer diameter 30.5 mm, inner hole diameter 20.5 mm, height 5 mm, and metal housing shell thickness 0.5 mm.

The ring magnet 24 is made of NdFeB, the magnet model number is N35, the coercive force is 876 kA/m, the permeability is 1.05, and the magnet is processed as follows: outer diameter is 29 mm, the inner diameter is 19 mm, the height is 4.5 mm, the magnetization direction is radial, and it constitutes the ring-shaped magnetic field enhancement portion.

When in use, after combining the ring-shaped magnetic field enhancement portion and the sample, put them into the sheet-shaped sample introduction cell. After the radio frequency power is activated, the current passes through the sample introduction rod and the housing shell and is conducted to the sample, the apparatus forms a magnetic field on the side of the sample which near the discharge chamber.

After use, if the magnet enhancement means is taken out and kept away from strong current and heat, while avoiding knocking and violent vibration, it can be reused.

### Embodiment 4

The present invention is further described below through another embodiment. In the following embodiment, the signal intensity of typical elements detected by a radio frequency glow discharge mass spectrometer with the magnetic field enhancement portion is compared with the signal intensity of typical elements detected by a radio frequency glow discharge mass spectrometer without the magnetic field enhancement portion; the greater the difference between them, the better the signal enhancement effect. The relative standard deviation (RSD %) is used to indicate the discharge stability of the non-conductor samples analyzed with the new apparatus; the lower the value, the better the stability.

The original yttrium oxide (Y₂O₃), Bi₁₂SiO₂₀ (BSO) and Ba_{5.52}La_{0.32}Ti₂Nb₈O₃₀ (BTN) material is processed into a disc-shaped sample. The dimensions of the sample are: cross-sectional diameter 20 mm, thickness 2 mm; washing the sample with nitric acid (HNO₃), ultrapure water and ethanol, then drying. Subsequently, the samples are rf-GD-MS analyzed under the conditions of radio frequency source power: 30 W and discharge gas (Ar) flow rate: 1.1 cc/min. Yin Y₂O₃, Bi in BSO and Ba in BTN are detected by rf-GD-MS with the ring magnet enhancement portion, the signal intensity of the ions are: 1.91×10⁻¹¹ A, 2.55×10⁻¹¹ A, 2.17×10⁻¹¹ A, the relative standard deviations RSD (%) are: 9.8, 10.3, 10.7. Y in Y₂O₃, Bi in BSO and Ba in BTN are detected by rf-GD-MS without the ring magnet enhancement portion, the signal intensity of the ions are: 9.54×10⁻¹² A, 1.65×10⁻¹¹ A, 1.03×10⁻¹¹ A, the relative standard deviations RSD (%) are: 10.5, 11.5, 12.7. The comparison result shows that the signal intensity of the ions and discharge stability obtained by rf-GD-MS analysis when using the ring magnet enhancement portion have been significantly enhanced and improved.

The third kind of apparatus provided by the present invention is an apparatus for enhancing signal intensity of radio frequency glow discharge mass spectrometry by adjustable magnetic field.

FIG. 6 shows the sectional view of the sample introduction cell in the apparatus for enhancing signal intensity of radio frequency glow discharge mass spectrometry by using adjustable magnetic field according to an embodiment of the present invention.

As shown in FIG. 6, the apparatus for enhancing signal intensity of radio frequency glow discharge mass spectrometry by using adjustable magnet field according to the embodiment mainly comprises: a sample introduction cell having a sample introduction rod 310 and having a sample 34 fixed thereon, and an adjustable magnetic field enhancement portion having a housing shell 35 and an electromagnet. The electromagnet is composed of energized solenoid and iron core. The electromagnet is placed in the housing shell 35 to form an adjustable magnetic field enhancement portion, and the combination is placed between the sample 34 and the sample introduction rod 310.

More specifically, a tantalum sheet 31, ceramic gaskets 32, 33, and the sample 34 are placed flat above the housing shell 35 in turn. The surfaces of the tantalum sheet 31 and the ceramic gaskets 32, 33 are flat and smooth. The ceramic gaskets 32, 33 are insulated and used to maintain vacuum; the tantalum sheet 31 is used for electrical conduction, which is movably placed between the ceramic gaskets 32,33 and the top of the sample introduction cell for easy disassembly and cleaning. The upper and lower surfaces of sample 34 and housing shell 35 are smooth surfaces. A solenoid 36 is placed inside of the housing shell 35, and the upper and lower surfaces are tightly attached the housing shell 35. Sheet sample cells 37,38,39 are connected together, and the sample cells are viewed as a whole from the outside. The sample introduction rod 310 is connected to the housing shell 35 for fixing the tantalum sheet 31, the ceramic gaskets 32, 33, the sample 34, the housing shell 35, and the solenoid 36. There is a spring which is not shown in drawings between the sample introduction rod 310 and the housing shell 35 to clamp them. A metal core (iron core) 311 is placed in the center of the solenoid 36 and is the core component of the solenoid magnet apparatus. A lead 312 passes through a small hole reserved outside the sample cell for energization. Specifically, the adjustable magnetic field enhancement portion is placed and fixed between the sample and the sample introduction rod, the lead passes through the small hole of the sample introduction cell and connects to the power supply (AC or DC). The current can be adjusted as needed to form a magnetic field enhancement means. In the radio frequency mode, the radio frequency current passes through the sample introduction rod 310 and the housing shell 35 and is conducted to the sample 34, the magnetic field magnitude of the magnetic field enhancement means is controlled by an external power supply, the electromagnetic field enhancement means can generate an oscillating magnetic field, thereby extending the movement path of electrons, increasing the collision probability of electrons and neutral particles, improving the ionization efficiency, and thus, improving the ion signal intensity. The structure of the present invention is simple and reasonable, which effectively improves the signal intensity and analysis sensitivity of the instrument, is suitable for element analysis of inorganic materials, and is convenient to use.

Further, it is better to use soft iron or silicon steel as the iron core for the electromagnet. Electromagnetic induction coil (the number of turns n≥5) is warped on the outside of the iron core, the electromagnet is placed in the housing shell 35 and makes it tightly attach to the housing shell 35 and fill the housing shell 35, and the lead of the solenoid passes through two small holes on the side of the housing shell 35 to constitute an adjustable magnetic field enhancement portion. The dimensions of the electromagnet are: the length of the electromagnet is less than the inner diameter of the housing shell 35, the diameter is less than the height of the housing shell 35, and the number of coil turns: n≥5. The electromagnet is placed in the housing shell 35 and is fixed using insulating material, and the lead 312 of the solenoid 36 is passed through the two small holes on the side of the housing shell 35.

The sample 34 that can be analyzed with radio frequency glow discharge mass spectrometry includes: conductors, semiconductors, non-conductor materials, etc. The material of the housing shell 35 can be metal (such as copper) or alloy (such as brass).

Referring to FIG. 6 and FIG. 7, the housing shell 35 can be a cylinder, a cube, or a cuboid. The processing size: the outer diameter (diameter) of the housing shell 35 is less than or equal to the inner diameter of the sample introduction cell, and the height of the housing shell is less than the height of the sample introduction cell. The upper surface and the lower surface of the housing shell 35 are preferably smooth and flat.

The method for enhancing signal intensity of radio frequency glow discharge mass spectrometry by using adjustable magnetic field provided by the present invention uses a sample introduction cell having a sample introduction rod 310 and having a sample 34 fixed thereon, and an adjustable magnetic field enhancement portion having a housing shell 35 and an electromagnet composed of an energized solenoid and an iron core, and may include the following steps:

put the adjustable magnetic field enhancement portion between the sample 34 and the sample introduction rod 310,

make the lead 312 of the energized solenoid pass through the small holes on the side of the housing shell and connect to the power supply;

connect the radio frequency source, adjust to proper discharge pressure and radio frequency source power to discharge; and

scan elements to be tested of the sample and record the signal intensity.

In addition, the manufacturing of the adjustable magnetic field enhancement portion of the present invention may include the following steps:

1. Process the housing shell 35 in the shape of a hollow cylinder, hollow cube or hollow cuboid, the material of the housing shell 35 is metal or alloy.

2. Select a metal core 311, coil the enameled wire on the metal core 311 to make an electromagnet.

3. Put the electromagnet into the housing shell 35 and fix it using insulating material, make the lead 312 of the solenoid 36 pass through two small holes on the side of the housing shell 35, the diameter of the small hole is adapted to the diameter of the lead 312.

4. Place the adjustable magnetic field enhancement portion between the sample 34 and the sample introduction rod 310, make the lead 312 pass through the small holes reserved outside the sheet-shaped discharge chamber and connect to the power supply (DC or AC).

The third kind of apparatus and its beneficial effects of the present invention will be specifically described below through embodiment 5 and embodiment 6.

### Embodiment 5

The present invention is further described below through an embodiment. The metal material is processed into a cylindrical housing shell (taking brass material and cylindrical shape as an example) at normal temperature and pressure. The dimensions of the brass housing shell are: bottom diameter 50 mm, height 5 mm, and brass housing shell thickness 0.5 mm. The dimensions of the solenoid are: metal core diameter 4 mm, length 49 mm, lead diameter 1 mm, and the number of turns: 45. The solenoid is placed in the brass housing shell and is fixed using insulating material, and the lead of the solenoid passes through the two small holes on the side of the housing shell. The signal enhancement means is placed between the sample and the sample introduction rod, and the lead passes through the small hole of the sheet-shaped discharge chamber and connects to the power supply (taking a DC power supply as an example) to form an adjustable magnetic field enhancement portion.

When in use, after combining the electromagnet and the sample, they are put into the sheet-shaped sample introduction cell. After the radio frequency power is activated, the current passes through the sample introduction rod and the housing shell and is conducted to the sample, the apparatus forms a magnetic field on the side of the sample which near the discharge chamber.

After use, if the magnet enhancement means is taken out and kept away from strong current and heat, while avoiding knocking and violent vibration, it can be reused.

### Embodiment 6

The present invention is further described below through another embodiment below. In the following embodiment, the signal intensity of typical elements detected by a radio frequency glow discharge mass spectrometer with the adjustable magnetic field enhancement portion is compared with the signal intensity of typical elements detected by a radio frequency glow discharge mass spectrometer without the adjustable magnetic field enhancement portion; the greater the difference between the two, the better the signal enhancement effect. The relative standard deviation (RSD %) is used to indicate the discharge stability of the non-conductor samples analyzed with the new apparatus; the lower the value, the better the stability.

Taking the analysis of the non-conductor material by using the adjustable magnetic field enhancement portion as an example, the original yttrium oxide (Y₂O₃), Bi₁₂SiO₂₀ (BSO) and Ba_{5.52}La_{0.32}Ti₂Nb₈O₃₀ (BTN) material is processed into a disc-shaped sample. The dimensions of the sample are: cross-sectional diameter 20 mm, thickness 2 mm. The sample is washed with nitric acid (HNO₃), ultrapure water, and ethanol, then dried. Subsequently, the samples are analyzed under the conditions of radio frequency source power: 30 W and discharge gas (Ar) flow rate: 1.1 cc/min. Y in Y₂O₃, Bi in BSO and Ba in BTN are detected by rf-GD-MS with the adjustable magnetic field enhancement portion, the signal intensity of the ions are: 1.85×10⁻¹¹ A, 2.56×10⁻¹¹ A, and 2.12×10⁻¹¹ A. The relative standard deviations RSD (%) are: 8.5, 9.3, 9.7. Y in Y₂O₃, Bi in BSO and Ba in BTN are detected by rf-GD-MS without the adjustable magnetic field enhancement portion, the signal intensity of the ions are: 9.54×10⁻¹² A, 1.65×10⁻¹¹ A, 1.03×10⁻¹¹ A, the relative standard deviations RSD (%) are: 10.5, 11.5, 12.7. The comparison result shows that the signal intensity of the ions and discharge stability obtained by rf-GD-MS analysis when using the adjustable magnetic field enhancement portion have been significantly enhanced and improved.

### INDUSTRIAL APPLICABILITY

The present invention provides three structural designs of the apparatus for enhancing signal intensity of radio frequency glow discharge mass spectrometry (rf-GD-MS) with a simple structure, low cost and stable performance, which enhance signal intensity of ions during material testing using radio frequency glow discharge mass spectrometry (rf-GD-MS), have advantages of simple structure, low cost, stable performance, etc., and can be widely promoted and applied, suitable for radio frequency glow discharge mass spectrometer or similar devices.

1. An apparatus for enhancing signal intensity of radio frequency glow discharge mass spectrometry, comprising:
a sample introduction cell having a sample introduction rod and having a sample fixed thereon; and
an array magnets enhancement portion having a housing shell and magnets arranged in array, wherein
the array magnets enhancement portion is fixed between the sample introduction rod and the sample in the sample introduction cell, and is tightly attached to the sample.

2. The apparatus for enhancing signal intensity of radio frequency glow discharge mass spectrometry according to claim 1, wherein
the magnets arranged in an array are placed in the housing shell, and direction of magnetic induction of each magnet is parallel to the sample.

3. A method for enhancing signal intensity of radio frequency glow discharge mass spectrometry, using an apparatus comprises a sample introduction cell having a sample introduction rod and having a sample fixed thereon, and an array magnets enhancement portion having a housing shell and magnets arranged in an array, the method comprising the following steps:
installing and fixing the array magnets enhancement portion between the sample introduction rod and the sample in the sample introduction cell, and making the portion tightly attach to the sample;
turning on a radio frequency source, so that current passes through the sample introduction rod and the housing shell and is conducted to the sample, and the apparatus forms a magnetic field on the side of the sample which is near a discharge chamber; and
scanning elements to be tested of the sample and recording signal intensity.

4. An apparatus for enhancing signal intensity of radio frequency glow discharge mass spectrometry, comprising:
a sample introduction cell having a sample introduction rod and having ceramic gaskets fixed thereon; and
a ring magnet enhancement portion having a housing shell and a ring magnet, wherein the ring magnet is placed in the housing shell, and the ring magnet enhancement portion is fixed between the sample introduction rod and the ceramic gaskets in the sample introduction cell.

5. The apparatus for enhancing signal intensity of radio frequency glow discharge mass spectrometry according to claim 4, wherein
a sample to be tested is placed in an inner hole of the ring magnet.

6. A method for enhancing signal intensity of radio frequency glow discharge mass spectrometry, using an apparatus comprises a sample introduction cell having a sample introduction rod and having ceramic gaskets fixed thereon, and a ring magnet enhancement portion having a housing shell and a ring magnet, the method comprising the following steps:
installing and fixing the ring magnet enhancement portion between the sample introduction rod and the ceramic gaskets in the sample introduction cell;
embedding a sample into an inner hole of the ring magnet;
connecting a radio frequency source, and adjusting to proper discharge pressure and radio frequency source power to discharge; and
scanning elements to be tested of the sample and recording signal intensity.

7. An apparatus for enhancing signal intensity of radio frequency glow discharge mass spectrometry, comprising:
a sample introduction cell having a sample introduction rod and having a sample fixed thereon; and
an adjustable magnetic field enhancement portion having a housing shell and an electromagnet composed of an energized solenoid and an iron core, wherein
the electromagnet is placed in the housing shell, and
the adjustable magnetic field enhancement portion is fixed between the sample introduction rod and the sample in the sample introduction cell.

8. The apparatus for enhancing signal intensity of radio frequency glow discharge mass spectrometry according to claim 7, wherein
the electromagnet is fixed in the housing shell using insulating material, and
a lead of the energized solenoid passes through two small holes on the side of the housing shell and connects to a power supply.

9. A method for enhancing signal intensity of radio frequency glow discharge mass spectrometry, using an apparatus comprises a sample introduction cell having a sample introduction rod and having a sample fixed thereon, and an adjustable magnetic field enhancement portion having a housing shell and an electromagnet composed of an energized solenoid and an iron core, the method comprising the following steps:
putting the adjustable magnetic field enhancement portion between a sample and the sample introduction rod;
making a lead of the energized solenoid pass through small holes reserved outside a sample cell and connect to a power supply;
connecting a radio frequency source, and adjusting to proper discharge pressure and radio frequency source power to discharge; and
scanning elements to be tested of the sample and recording signal intensity.
